(19) United States
(12) Patent Application Publication
(10) Pub. No.: US 2020/0291514 A1
(43) Pub. Date: Sep. 17, 2020

(54) Film Forming Apparatus and Film Forming Method

(71) Applicant: TOKYO ELECTRON LIMITED, Tokyo (JP)

(72) Inventor: Einosuke TSUDA, Nirasaki City (JP)

(21) Appl. No.: 16/809,847

(22) Filed: Mar. 5, 2020

(30) Foreign Application Priority Data
Mar. 11, 2019 (JP) 2019-044094

(51) Int. Cl. C23C 16/448; C23C 16/06; C23C 16/44

(52) U.S. Cl. CPC C23C 16/448; C23C 16/4412; C23C 16/06

(57) ABSTRACT

An apparatus for forming a predetermined film on a substrate, includes a processing container into which a film-forming raw material gas is introduced, a stage provided inside the processing container, and a housing body provided below the processing container and communicating with an exhaust port provided in a bottom portion of the processing container. The housing body includes a housing section that houses a support member of the stage, and a manifold section opened toward the housing section while being in communication with an exhaust device. An exhaust space is formed at a side of a lower surface of the stage. Atmosphere above the stage flows into the exhaust space along a peripheral portion of the stage. The housing section is smaller in horizontal cross-sectional area than the exhaust space. An inlet of the housing section is smaller in cross-sectional area than an outlet of the housing section.

### CROSS-REFERENCE TO RELATED APPLICATION

This application is based upon and claims the benefit of priority from Japanese Patent Application No. 2019-044094, filed on Mar. 11, 2019, the entire contents of which are incorporated herein by reference.

### TECHNICAL FIELD

The present disclosure relates to a film forming apparatus and a film forming method.

### BACKGROUND

Patent Document 1 discloses a low-pressure chemical vapor deposition apparatus (LPCVD apparatus) which includes a reaction chamber, a vacuum exhaust device, and a manifold connecting the reaction chamber and the vacuum exhaust device. In the LPCVD apparatus, conductance between the reaction chamber and the manifold is sufficiently higher than the exhaust speed of the vacuum exhaust device.

### PRIOR ART DOCUMENT

### Patent Document

Patent Document 1: Japanese Laid-Open Patent Publication No. 2001-257171

### SUMMARY

According to an embodiment of the present disclosure, there is provided a film forming apparatus for forming a predetermined film on a substrate, including: a processing container configured to be capable of being depressurized and into which a film-forming raw material gas generated by vaporizing a liquid raw material or a solid raw material is introduced; a stage provided inside the processing container and configured to place the substrate thereon; and a housing body provided below the processing container and communicating with an exhaust port provided in a bottom portion of the processing container, wherein the housing body includes a housing section configured to house a support member of the stage, and a manifold section provided on a side of the housing section and opened toward the housing section, the manifold section being in communication with an exhaust device, wherein an exhaust space is formed at a side of a lower surface of the stage inside the processing container, and atmosphere above the stage flows into the exhaust space along a peripheral portion of the stage, and wherein a horizontal cross-sectional area of the housing section is smaller than a horizontal cross-sectional area of the exhaust space, and a cross-sectional area of an inlet of the housing section is smaller than a cross-sectional area of an outlet of the housing section.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an explanatory view schematically illustrating the configuration of a film forming apparatus according to an embodiment.

FIG. 2 is a perspective view of a housing body in the film forming apparatus of FIG. 1.

FIG. 3 is an explanatory view schematically illustrating the housing body of FIG. 2.

FIG. 4 is an explanatory plan view schematically illustrating another example of the housing body.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a semiconductor device manufacturing process, various kinds of processes such as a film forming process of forming a predetermined film such as a metal film are repeatedly performed on a semiconductor wafer (hereinafter, referred to as a “wafer”), whereby a desired semiconductor device is manufactured.

In the film forming process, a solid raw material or a liquid raw material may be heated and vaporized so as to form a film-forming raw material gas. For example, when forming a ruthenium (Ru) film, Ru₃(CO)₁₂, which is a solid raw material, is heated for sublimation, and a raw material gas thus generated is caused to flow into a processing container of a film forming apparatus by a carrier gas.

In this regard, as described above, the technology disclosed in Patent Document 1 discloses a low-pressure chemical vapor deposition apparatus (LPCVD apparatus) including a reaction chamber, an evacuation device, and a manifold that connects the reaction chamber and the evacuation device, in which the conductance between the reaction chamber and the manifold is sufficiently higher than an evacuation speed of the evacuation device. However, as an apparatus configuration for realizing this, there is described only a configuration, in which a manifold and a cylindrical reaction furnace are integrated without separation, and exhaust is performed through a turbo molecular pump and a rotary pump directly installed in the manifold via a gate valve and a conductance valve.

The technology disclosed in Patent Document 1 is a batch-type processing apparatus in which a plurality of substrates are placed vertically, and the heating of the substrates is performed by a heater provided outside the reaction furnace. In addition, the apparatus of the technology disclosed in Patent Document 1 does not have a function of vertically moving the substrates up and down, and merely places the substrates on an open-type container having a plurality of slots, generally called a wafer boat.

The technology disclosed in Patent Document 1 is not directly applicable to a single-wafer-type film forming apparatus that processes the substrates one by one. In such a single-wafer-type film forming apparatus, uniformity of processing is extremely important. Thus, for example, when a ruthenium (Ru) film is formed on a substrate such as a wafer, it is required that the substrate is placed on a stage having a built-in heater, a raw material gas is supplied from above the substrate, and exhaust is uniformly performed from a peripheral portion of the substrate. In addition, a lifting mechanism needs to be provided at the side of a lower surface of the stage to perform loading/unloading of the substrate. Thus, it is difficult to directly apply the technology disclosed in Patent Document 1 to such an apparatus configuration. In addition, the problem of uniform exhaust still remains.

Hereinafter, a film forming apparatus and a film forming method according to the present embodiment will be described with reference to the drawings. In the specification and drawings, elements having substantially the same functional configuration will be denoted by the same reference numeral and redundant description thereof will be omitted.

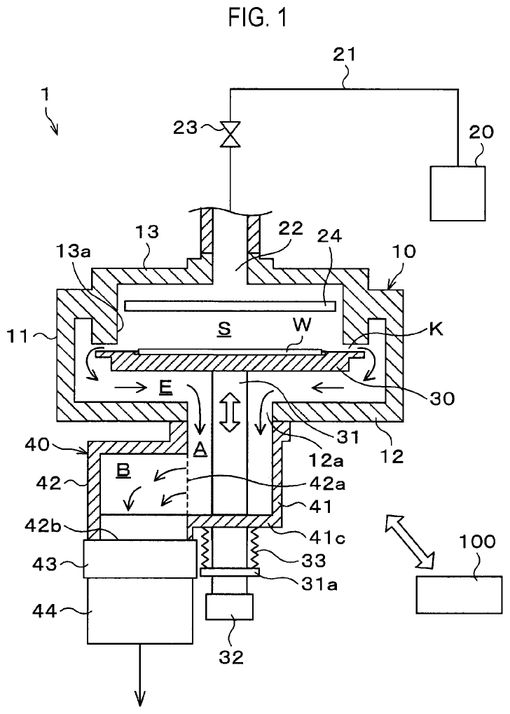

FIG. 1 is an explanatory view schematically illustrating the configuration of a film forming apparatus 1 according to an embodiment, in which a portion of the film forming apparatus 1 is illustrated in a cross section. The film forming apparatus 1 of the present embodiment is configured to form a Ru film on a wafer W as a substrate using Ru₃(CO)₁₂, which is a solid raw material as a film forming material.

As illustrated in FIG. 1, the film forming apparatus 1 includes a processing container 10 which is capable of being depressurized and configured to accommodate therein a wafer W as a substrate, and a raw material gas supply mechanism 20 configured to supply a film-forming raw material gas to the processing container 10.

The processing container 10 whose interior is formed in a cylindrical shape is made of, for example, a metal material (e.g., an aluminum alloy). A loading/unloading port (not illustrated) through which the wafer W is transferred is formed in a sidewall 11 of the processing container 10. A gate valve (not illustrated) for opening/closing the loading/unloading port is provided in the loading/unloading port.

The raw material gas supply mechanism 20 has a raw material tank for storing the above-mentioned solid raw material. The solid raw material stored in the raw material tank is sublimated to form gas. The gas is supplied from a supply part 22 provided at an upper center of the interior of the processing container 10 into the processing container 10 through a supply pipe 21 together with a carrier gas (e.g., CO). The supply pipe 21 is provided with a valve 23. In addition, the supply pipe 21 is provided with a heating mechanism (not illustrated) in order to maintain the raw material gas in the supply pipe 21 at a predetermined temperature.

A stage 30 on which the wafer W is placed horizontally and which has a circular shape in a plan view is provided inside the processing container 10. A heater (not illustrated) for heating the wafer W and a chiller flow path (not illustrated) are provided inside the stage 30. A support member 31 configured to support the stage 30 is provided on the central portion of a lower surface of the stage 30. The support member 31 passes through an exhaust port 12a formed in the center of a bottom wall 12 of the processing container 10.

A lower end of the support member 31 is connected to a lifting mechanism 32. By driving the lifting mechanism 32 under the control of a controller 100 to be described later, the stage 30 is movable up and down between a first position defined at the upper side and a second position defined at the lower side. FIG. 1 illustrates the state in which the stage is positioned at the first position.

The first position is a processing position at which a film forming process is performed on the wafer W. A processing space S is formed above the stage 30 by the stage 30 located at the processing position and an annular partition wall 13a extending from a ceiling wall 13 of the processing container 10 to a peripheral portion of the stage 30. When the stage 30 is positioned at the processing position, an annular gap K is formed between the peripheral portion of the upper surface of the stage 30 and a lower surface of the partition wall 13a. An internal atmosphere of the processing space S is exhausted from the side of the lower surface of the stage 30 through the gap K.

The second position is a standby position where the stage 30 waits to deliver the wafer W between a transfer mechanism (not illustrated) of the wafer W entering the processing container 10 through the above-described loading/unloading port (not illustrated) formed in the processing container 10 and lifting pins (not illustrated) provided below the stage 30.

A baffle plate 24 as a gas flow forming member for forming a flow of the raw material gas in the processing space S is provided above the stage 30 in the processing container 10 in a parallel relationship with the stage 30. The baffle plate 24 is a member that vertically partitions the processing space S, and is supported by a support member (not illustrated). The raw material gas supplied from the aforementioned supply part 22 provided in the center of the ceiling wall 13 moves outwards along an upper surface of the baffle plate 24 and then moves downwards from the outer portion of the baffle plate 24. Then, the raw material gas flows towards an upper surface of the wafer W on the stage 30.

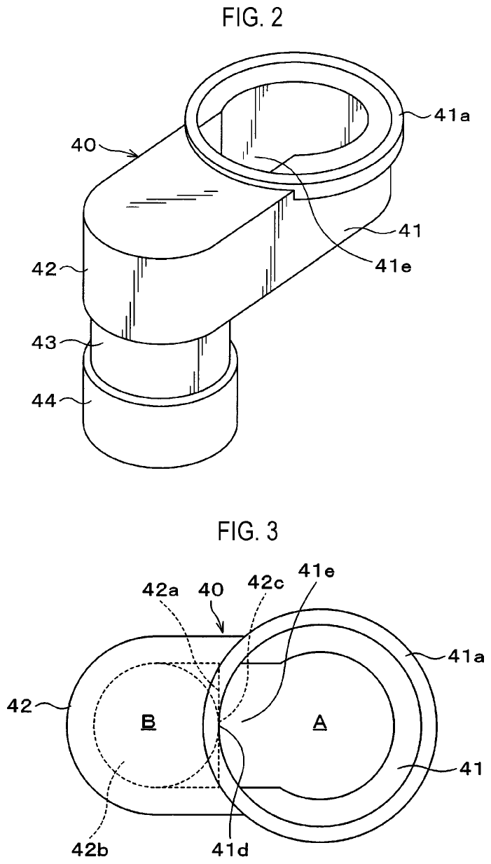

As illustrated in FIG. 2, a housing body 40 is provided in the exhaust port 12a. More specifically, the housing body 40 has a housing section 41 configured to house the support member 31 and a manifold section 42 integrated with the housing section 41. An annular portion 41a on an upper surface of the housing section 41 is airtightly connected to a peripheral portion of the exhaust port 12a in the bottom wall 12.

An inlet opening portion 42a of the manifold section 42 is rectangular in a front view and is opened with respect to the housing section 41. An outlet opening portion 42b of the manifold section 42 has circular shape. An APC valve 43 configured to function as a pressure regulating valve is provided in the outlet opening portion 42b of the manifold section 42. The APC valve 43 has an automatic pressure regulating function and a shutoff function. An opening degree of the APC valve 43 is controlled based on a control signal provided from the controller 100 to be described later, and thus an exhaust flow rate and the like are controlled. The APC valve 43 used in the present embodiment has a diameter of 200 mm and an allowable differential pressure of 7.0 Torr. An exhaust device 44 is connected to the downstream side of the APC valve 43. As the exhaust device 44, for example, a turbo molecular pump may be used. In the present embodiment, a turbo molecular pump having a capacity of 1,500 L/s is used.

A flange 31a is provided on the support member 31 outside a bottom wall 41c of the housing section 41. A bellows 33 is provided between an upper surface of the flange 31a and a lower surface of the bottom wall 41c of the housing section 41 so as to surround an outer periphery of the support member 31. The bellows 33 prevents airtightness from being lost at a portion through which the support member 31 penetrates in the bottom wall 41c of the housing section 41.

In the film forming apparatus 1 configured as above, a horizontal cross-sectional area of the housing section 41 is set to be smaller than that of the exhaust space E. For example, the horizontal cross-sectional area of the housing section 41 may be 50% or less of that of the exhaust space E, specifically 25% to 35%. In the present embodiment, the exhaust port 12a formed in the center of the bottom wall 12 of the processing container 10 and the housing section 41 have the same horizontal cross-sectional area.

In the housing body 40 of the film forming apparatus 1, an inlet cross-sectional area of the housing section 41 is smaller than an outlet cross-sectional area of the housing section 41, namely a cross-sectional area of the inlet opening portion 42a of the manifold section 42. In other words, the inlet cross-sectional area of the manifold section 42 (the area of the inlet opening portion 42a) is set to be larger than the inlet cross-sectional area of the housing section 41. In addition, a volume B of the manifold section 42 illustrated in FIG. 3 is equal to or larger than a volume A of the housing section 41. That is, the volumes have a relationship of B≥A.

In addition, in the film forming apparatus 1 according to the present embodiment, as illustrated in FIG. 3, an opening end portion 41d at the side of the manifold section 42 in the inlet of the housing section 41 and an outlet of the manifold section 42, namely an opening end portion 42c, which is located closest to the hosing section 41 in the outlet opening portion 42b at the side of the APC valve 43, are located on the same straight line in a plan view.

As illustrated in FIG. 3, an inlet shape of the housing section 41 is a non-true circular shape in a plan view, and has an enlarged opening portion 41e at the side of the manifold section 42. That is, the housing section 41 has a non-true circular inlet shape as a whole in which the enlarged opening portion 41e protruding toward the manifold section 42 is formed in an opening of an approximately ¾ circular surrounding the support member 31.

The film forming apparatus 1 configured as described above is provided with the controller 100. The controller 100 is configured by, for example, a computer including a CPU, memory, and the like, and includes a program storage part (not illustrated). The program storage part also stores a program for controlling the APC valve 43, the valve 23, and the like in order to implement wafer processing in the film forming apparatus 1. The program may be recorded in a non-transitory computer-readable storage medium, and may be installed on the controller 100 from the storage medium. In addition, a portion or all of the program may be implemented by a dedicated hardware (circuit board).

Next, a film forming process performed on the wafer W using the film forming apparatus 1 will be described.

First, an internal pressure of the processing container 10 is measured in a state in which the valve 23 and the APC valve 43 are in the closed state, and an opening degree of the APC valve 43 is adjusted based on the measurement result, so that the interior of the processing container 10 is set to a predetermined pressure (e.g., 7 Torr to 10 Torr). In this state, the gate valve (not illustrated) provided in the wafer loading/unloading port (not illustrated) of the processing container 10 is opened. The transfer mechanism (not illustrated), which holds the wafer W, enters the processing container 10 from a transfer chamber (not illustrate) having a vacuum atmosphere and located adjacent to the processing container 10 through the loading/unloading port.

The wafer W is transferred to above the stage 30 located in the standby position described above. Subsequently, the wafer W is delivered on the lifting pins (not illustrated) staying in a raised state. Then, the transfer mechanism is withdrawn from the processing container 10, and the gate valve is closed. At the same time, the lifting pins are lowered and the stage 30 is raised so that the wafer W is placed on the stage 30. Then, the stage 30 moves to the above-described processing position, and the processing space S is formed above the wafer W.

Subsequently, the wafer W is heated to a predetermined temperature (e.g., 120 to 300 degrees C., specifically 130 to 250 degrees C.) by the heater (not illustrated) provided inside the stage 30. When the temperature of the wafer W reaches the predetermined temperature, the opening degree of the APC valve 43 is adjusted so that the internal pressure of the processing container 10 is reduced to a predetermined processing pressure, for example, 0.013 Pa to 133.3 Pa (0.1 mTorr to 1 Torr), specifically 1.3 Pa to 66.5 Pa (10 mTorr to 500 mTorr).

After the reduction in internal pressure of the processing container 10 is completed, the opening degrees of the valve 23 and the APC valve 43 are adjusted, and the supply of Ru₃(CO)₁₂, which is a film-forming raw material gas, into the processing space S in the processing container 10 is performed at a predetermined flow rate having a range of, for example, 0.1 sccm to 3.0 sccm, specifically 0.2 sccm to 1.0 sccm. In addition, CO as a carrier gas is caused to flow at a flow rate of 10 sccm to 300 sccm. Thus, the formation of a Ru film on the wafer W is initiated. Then, after the formation of the Ru film is completed, the operations of the valves are performed in an order opposite the above order, and the wafer W is unloaded from the processing container 10.

During the film forming process, the flow of the gas inside the processing container 10 is defined as indicated by arrows in FIG. 1. That is, the gas flows downward from the annular gap K between the peripheral portion of the upper surface of the stage 30 and the lower surface of the partition wall 13a and is once collected in the exhaust space E. Thereafter, the gas flows from the exhaust port 12a having a horizontal cross-sectional area smaller than that of the exhaust space E to the inlet of the housing section 41 of the housing body 40.

In this case, since the exhaust port 12a and the inlet of the housing section 41 are located in the center of the exhaust space E, the gas is uniformly exhausted from the peripheral portion of the stage 30 when flowing from the gap K to the exhaust space E. After being once collected in the exhaust space E, the gas is concentrated and exhausted toward the exhaust port 12a and the inlet of the housing section 41. Subsequently, the gas that has flown into the housing section 41 flows into the manifold section 42.

Since the cross-sectional area of the inlet of the manifold section 42 (the area of the inlet opening portion 42a) is set to be larger than the cross-sectional area of the inlet of the housing section 41, the conductance when an internal atmosphere of the housing section 41 flows into the manifold section 42 is large. Therefore, it is possible to perform suitable film forming process by performing appropriate exhaust even under a low pressure. Moreover, in the above embodiment, the volume B of the manifold section 42 is set to be larger than the volume A of the housing section 41. Accordingly, it is possible to make the internal atmosphere of the housing section 41 flow to the APC valve 43 and the exhaust device 44 in an extremely smooth manner Therefore, it is easy to reduce the internal pressure of the processing space S of the processing container 10 to a pressure lower than that in the related art.

Since the inlet of the housing section 41 has a non-true circular shape as a whole in a plan view and the housing section 41 has the enlarged opening portion 41e at the side of the manifold section 42, the conductance of the shape of the inlet of the housing section 41 is increased depending on the shape of the inlet opening portion 42a of the manifold section 42. Of course, the shape of the inlet of the housing section 41 is not limited thereto, and an arbitrary enlarged opening portion 41e may be adopted depending on the shape of the inlet opening portion 42a of the manifold section 42.

In addition, in the film forming apparatus 1 according to the present embodiment, the opening end portion 41d at the side of the manifold section 42 in the inlet of the housing section 41 and the outlet of the manifold section 42, namely the opening end portion 42c, which is located closest to the hosing section 41 in the outlet opening portion 42b at the side of the APC valve 43, are located on the same straight line in a plan view. Accordingly, the conductance when exhausting the gas from the interior of the housing section 41 to the manifold section 42, the APC valve 43, and the exhaust device 44 is maximized for the housing body 40 having a configuration in which the APC valve 43 and the exhaust device 44 are not located immediately below the housing section 41.

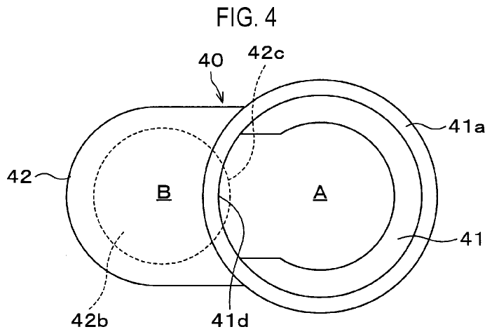

In such a case, as illustrated in FIG. 4, the outlet of the manifold section 42, namely the opening end portion 42c located closest to the housing section 41 in the outlet opening portion 42b at the side of the APC valve 43, may be located closer to the side of the housing section 41 than the opening end portion 41d positioned at the side of the manifold section 42 in the inlet of the housing section 41. That is, as illustrated in FIG. 4, the opening end portion 42c in the manifold section 42 may be located inward of the inlet of the housing section 41 in a plan view. This makes it possible to further increase the conductance at the time of exhaust, and perform the film forming process at a lower pressure.

Then, when the Ru film was formed on the front surface of the wafer W under the above-mentioned conditions, it was possible to improve the deposition rate of Ru compared with the conventional Ru film forming process of about 100 mTorr. The thickness of the Ru film on the front surface of the wafer W was good in uniformity. It is presumed that this is because the gas from the processing space S is first gathered in the exhaust space E, followed by being collectively exhausted toward the exhaust port 12a, which is located directly below the exhaust space E and having a horizontal cross-sectional area smaller than that of the exhaust space E, and the inlet of the housing section 41, followed by causing the gas to flow from the housing section 41 into the manifold section 42 having a larger volume.

Moreover, in the present embodiment, it was possible to accurately control the internal pressure of the processing container from 7 Torr 10 Torr, which is used in a preparation stage before the film forming process, to 0.1 mTorr to 1 Torr, which is a pressure used during the film forming process. Moreover, the opening degree of the APC valve 43 was realized at 30%, which is smaller than 50% as the general rated maximum opening degree (opening degree that guarantees control). This was obtained by setting the structure of the housing body 40 according to the embodiment such that the cross-sectional area of the inlet of the manifold section 42 (the area of the inlet opening portion 42a) is set to be larger than that of the inlet of the housing section 41 and the volume B of the manifold section 42 is set to be larger than the volume A of the housing section 41.

In addition, the housing body 40 adopted in the above-described embodiment is provided so as to be merely connected to the exhaust port in the bottom portion of the processing container in the film forming apparatus having the lifting mechanism or the like provided below the stage. Thus, it is possible to implement the housing body 40 without largely modifying the existing apparatus. This can be achieved by removing the exhaust pipe connected to the exhaust port in the bottom portion of the processing container of this type of existing film forming apparatus and connecting the housing body 40 to the exhaust port. Thus, the good practicability is provided.

In the above description, Ru₃(CO)₁₂ is used as the solid raw material for a Ru film, but other solid raw materials may be used. In addition, the present disclosure is applicable to a low-pressure film forming process using a liquid raw material instead of the solid raw material. The solid raw material means a raw material, which is solid at atmospheric pressure and room temperature, and the liquid raw material means a raw material, which is liquid at atmospheric pressure and room temperature.

While in the above examples, there has been described the example in which the Ru film is formed, the technology according to the present disclosure is applicable to an apparatus for forming another film using a raw material gas generated by vaporizing a solid raw material or a liquid raw material.

While in the above description, the CO gas has been described to be used as a carrier gas, a noble gas such as an Ar gas, or an inert gas such as N₂ may be used as the carrier gas. However, when the CO gas is used, it is possible to prevent the raw material gas from decomposing.

It should be noted that the embodiments disclosed herein are exemplary in all respects and are not restrictive. The above-described embodiments may be omitted, replaced or modified in various forms without departing from the scope and spirit of the appended claims.

The following configurations also belong to the technical scope of the present disclosure.

(1) A film forming apparatus for forming a predetermined film on a substrate, includes: a processing container configured to be capable of being depressurized and into which a film-forming raw material gas generated by vaporizing a liquid raw material or a solid raw material is introduced; a stage provided inside the processing container and configured to place the substrate thereon; and a housing body provided below the processing container and communicating with an exhaust port provided in a bottom portion of the processing container, wherein the housing body includes a housing section configured to house a support member of the stage, and a manifold section provided on a side of the housing section and opened toward the housing section, the manifold section being in communication with an exhaust device, wherein an exhaust space is formed at a side of a lower surface of the stage inside the processing container, and atmosphere above the stage flows into the exhaust space along a peripheral portion of the stage, and wherein a horizontal cross-sectional area of the housing section is smaller than a horizontal cross-sectional area of the exhaust space, and a cross-sectional area of an inlet of the housing section is smaller than a cross-sectional area of an outlet of the housing section.

(2) In the film forming apparatus of (1) above, an end portion facing the manifold section in the inlet of the housing section and an end portion facing the housing section in an outlet of the manifold section are located on the same straight line in a plan view, or the end portion facing the housing section in the outlet of the manifold section is located closer to the housing section than the end portion facing the manifold section in the inlet of the housing section.

(3) In the film forming apparatus of (1) or (2) above, the horizontal cross-sectional area of the housing section is 50% or less of the horizontal cross-sectional area of the exhaust space in terms of a cross-sectional area ratio.

(4) In the film forming apparatus of any one of (1) to (3) above, a volume of the manifold section is equal to or larger than a volume of the housing section.

(5) In the film forming apparatus of any one of (1) to (4) above, the inlet of the housing section has a non-true circular shape, and includes an enlarged opening portion defined at a side of the manifold section.

(6) In the film forming apparatus of any one of (1) to (5) above, the film-forming raw material gas is a gas obtained by sublimating ruthenium

(7) A film forming method of forming a ruthenium film on a surface of a substrate by depositing ruthenium on the surface of the substrate using the film forming apparatus of any one of (1) to (6) above, includes: introducing a raw material gas obtained by sublimating the ruthenium into the processing container; heating the stage to a temperature of 120 degrees C. to 300 degrees C.; and performing a film forming process while maintaining an internal pressure of the processing container at 1.3 Pa to 66.5 Pa.

According to the technology of the present disclosure, in a film forming apparatus that forms a predetermined film on a substrate in a processing container using a raw material gas generated by vaporizing a raw material, it is possible to perform suitable film forming process by performing appropriate exhaust even under a low pressure.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus for forming a predetermined film on a substrate, comprising:
a processing container configured to be capable of being depressurized and into which a film-forming raw material gas generated by vaporizing a liquid raw material or a solid raw material is introduced;
a stage provided inside the processing container and configured to place the substrate thereon; and
a housing body provided below the processing container and communicating with an exhaust port provided in a bottom portion of the processing container,
wherein the housing body includes a housing section configured to house a support member of the stage, and a manifold section provided on a side of the housing section and opened toward the housing section, the manifold section being in communication with an exhaust device,
wherein an exhaust space is formed at a side of a lower surface of the stage inside the processing container, and atmosphere above the stage flows into the exhaust space along a peripheral portion of the stage, and
wherein a horizontal cross-sectional area of the housing section is smaller than a horizontal cross-sectional area of the exhaust space, and a cross-sectional area of an inlet of the housing section is smaller than a cross-sectional area of an outlet of the housing section.

2. The film forming apparatus of claim 1, wherein an end portion facing the manifold section in the inlet of the housing section and an end portion facing the housing section in an outlet of the manifold section are located on the same straight line in a plan view, or the end portion facing the housing section in the outlet of the manifold section is located closer to the housing section than the end portion facing the manifold section in the inlet of the housing section.

3. The film forming apparatus of claim 2, wherein the horizontal cross-sectional area of the housing section is 50% or less of the horizontal cross-sectional area of the exhaust space in terms of a cross-sectional area ratio.

4. The film forming apparatus of claim 3, wherein a volume of the manifold section is equal to or larger than a volume of the housing section.

5. The film forming apparatus of claim 4, wherein the inlet of the housing section has a non-true circular shape, and includes an enlarged opening portion defined at a side of the manifold section.

6. The film forming apparatus of claim 5, wherein the film-forming raw material gas is a gas obtained by sublimating ruthenium.

7. The film forming apparatus of claim 1, wherein the horizontal cross-sectional area of the housing section is 50% or less of the horizontal cross-sectional area of the exhaust space in terms of a cross-sectional area ratio.

8. The film forming apparatus of claim 1, wherein a volume of the manifold section is equal to or larger than a volume of the housing section.

9. The film forming apparatus of claim 1, wherein the inlet of the housing section has a non-true circular shape, and includes an enlarged opening portion defined at a side of the manifold section.

10. The film forming apparatus of claim 1, wherein the film-forming raw material gas is a gas obtained by sublimating ruthenium.

11. A film forming method of forming a ruthenium film on a surface of a substrate by depositing ruthenium on the surface of the substrate using the film forming apparatus of claim 1, the film forming method comprising:
introducing a raw material gas obtained by sublimating the ruthenium into the processing container;
heating the stage to a temperature of 120 degrees C. to 300 degrees C.; and
performing a film forming process while maintaining an internal pressure of the processing container at 1.3 Pa to 66.5 Pa.
